(19) United States
(12) Patent Application Publication
(10) Pub. No.: US 2007/0054442 A1
(43) Pub. Date: Mar. 8, 2007

(54) Method for manufacturing thin film transistor, thin film transistor and pixel structure

(76) Inventors: Po-Chih Liu, Lujhou City (TW); Chun-Hsiang Fang, Dongshan Township (TW); Ming-Che Ho, Bade City (TW); Chia-Chien Lu, Taipei City (TW)

Correspondence Address: J C PATENTS, INC., 4 VENTURE, SUITE 250, IRVINE, CA, 92618, US

(21) Appl. No.: 11/223,659

(22) Filed: Sep. 8, 2005

(51) Int. Cl. H01L 21/84; H01L 21/00

(52) U.S. Cl. 438/149

(57) ABSTRACT

A method for manufacturing a thin film transistor is provided. First, a poly-silicon island is formed on a substrate. Then, a patterned gate dielectric layer and a gate are formed on the poly-silicon island. Next, a source/drain is formed in the poly-silicon island beside the gate, wherein the region between the source/drain is a channel. Furthermore, a metal layer is formed on the substrate to cover the gate, the patterned gate dielectric layer and the poly-silicon island. Moreover, the metal layer above the source/drain will react with the poly-silicon island to form a silicide layer. Then, the non-reacted metal layer is removed. Afterwards, an inter-layer dielectric (ILD) is formed to cover the substrate. Then, the inter-layer dielectric above the source/drain is removed to form a source/drain contacting hole, wherein the silicide layer is used as an etching stopper.

### BACKGROUND OF THE INVENTION

1. Field of Invention

The present invention relates to a method for manufacturing thin film transistor, a thin film transistor and a pixel structure and particularly to a method for manufacturing thin film transistor having a source/drain contact hole made with precision tolerance, a thin film transistor and a pixel structure with fine operating properties.

2. Description of the Related Art

Following the development of the photoelectric technique, digitalized video or image device has become a common product in daily life. Among the digitalized video or image devices, display is an important human-computer interface. The users can read information from the display and further control the operation of the device.

The thin film transistor (TFT) is applied as the driving component in the display. Wherein, low temperature poly-silicon thin film transistor (LTPS TFT) is a technique different from the conventional amorphous silicon thin film transistor. The electron mobility of the LTPS can be over 200 cm²/V-sec. Therefore, the thin film transistor can be made in smaller size so that the aperture ratio is increased, the brightness of the display is enhanced and the power consumption is reduced.

FIG. 1A to FIG. 1E are cross-sectional diagrams illustrating the steps of the method for manufacturing conventional low temperature poly-silicon thin film transistor. First, referring to FIG. 1A, a buffer layer 110 and an amorphous layer 120 are formed on the substrate 100 and the amorphous layer 120 is then transformed into a poly-silicon layer 140 through excimer laser annealing (ELA) 130. Next, referring to FIG. 1B, the poly-silicon layer 140 is patterned into a plurality of poly-silicon islands 142 (only one is shown in FIG. 1B) and a gate dielectric layer 150 is formed on the substrate 100 to cover the poly-silicon island 142. Then, referring to FIG. 1C, a gate 160 is formed on the gate dielectric layer 150 above the poly-silicon island 142 and used as a self-aligned mask to proceed with an ion implantation 170 so that a source/drain 144 is formed in the poly-silicon island 142 beside the gate 160 and a channel 146 is disposed between the source/drain 144. Furthermore, referring to FIG. 1D, an inter-layer dielectric 180 is formed on the substrate 100 to cover the gate 160. Parts of the inter-layer dielectric 180 and the gate dielectric layer 150 above the source/drain 144 are removed through dry etching and wet etching to form a source/drain contact hole 190. Afterwards, referring to FIG. 1E, a source/drain metal layer 195 is formed on the inter-layer dielectric 180 and filled with the source/drain contact hole 190 to electrically connect with the source/drain 144. Hence, a low temperature poly-silicon thin film transistor 200 is formed.

Accordingly, as shown in FIG. 1D, the conventional technique fabricates the source/drain contact hole 190 using dry etching and wet etching. First, the dry etching is used to remove the inter-layer dielectric 180, wherein the material of the inter-layer dielectric 180 is usually silicon nitrides. According to the characteristic of anisotropic etching of the dry etching, the size of the source/drain contact hole 190 can be controlled more precisely. Next, the gate dielectric layer 150 is removed through wet etching and the material of the gate dielectric layer 150 is usually silicon oxides. However, because of the characteristic of isotropic etching of the wet etching, the etching capability of the wet etching is limited and the homogeneity of the wet etching is not easy to control. Therefore, the source/drain contact hole 190 cannot be made with precision tolerance. In addition, during removing the gate dielectric layer 150 above the source/drain 144, the source/drain 144 may be damaged through the above-described manufacturing process (as shown in FIG. lD) so that the operating property of the low temperature poly-silicon thin film transistor 200 is spoilt.

### SUMMARY OF THE INVENTION

Accordingly, an object of the present invention is to provide a method for manufacturing thin film transistor, the method is suitable for manufacturing a source/drain contact hole with precision tolerance without damaging the source/drain and further improves the operating property of the thin film transistor.

Another object of the present invention is to provide a thin film transistor, suitable for providing fine operating properties.

Another object of the present invention is to provide a pixel structure, suitable for providing fine operating properties.

The present invention provides a method for manufacturing thin film transistor, which includes following steps: first, a poly-silicon island is formed on the substrate. Next, a patterned gate dielectric layer and a gate are formed on the poly-silicon island. Then, a source/drain is formed in the poly-silicon island beside the gate, wherein a channel is disposed between the source/drain. Furthermore, a metal layer is formed on the substrate to cove the gate, the patterned gate dielectric layer and the poly-silicon island. Next, the metal layer and the poly-silicon island above the source/drain are reacted to form a silicide layer. Then, the non-reacted metal layer is removed. Moreover, an inter-layer dielectric is formed to cover the substrate. Afterwards, the inter-layer dielectric above the source/drain is removed to form a source/drain contact hole, wherein the silicide layer is used as an etching stopper.

According to an embodiment of the present invention, the method for forming the poly-silicon island on the substrate can include following steps: first, an amorphous layer is formed on the substrate. Next, the amorphous layer is transformed into a poly-silicon layer. Afterwards, the poly-silicon layer is patterned to form at least one of poly-silicon island. Wherein, the method for transforming the amorphous layer into the poly-silicon layer can be excimer laser annealing (ELA) or rapid thermal annealing (RTA).

According to an embodiment of the present invention, before forming the amorphous layer on the substrate, the method can further form a buffer layer on the substrate, wherein the material of the buffer layer can be silicon nitrides.

According to an embodiment of the present invention, the material of the foregoing metal layer can be selected from one of palladium (Pd), titanium (Ti), nickel (Ni), WTi, tungsten (W), cobalt (Co), tantalum (Ta), molybdenum (Mo), platinum (Pt), germanium (Ge) and the combination thereof.

According to an embodiment of the present invention, the foregoing method for forming the metal layer on the substrate can be sputtering or plasma deposition.

According to an embodiment of the present invention, the foregoing method for forming the silicide layer through the reaction of the metal layer and the poly-silicon island above the source/drain can be an annealing process.

According to an embodiment of the present invention, the foregoing method for removing the non-reacted metal layer can be a wet etching process.

According to an embodiment of the present invention, the foregoing method for removing the inter-layer dielectric above the source/drain can be a photolithography process and a dry etching, wherein the silicide layer is used as the etching stopper.

According to an embodiment of the present invention, after forming the source/drain contact hole, the method further forms a source/drain metal layer, which is filled with the source/drain contact hole and electrically connected to the source/drain.

The present invention provides a thin film transistor, suitable for the use in a display. The thin film transistor includes a substrate, a poly-silicon island, a patterned gate dielectric layer, a gate, a silicide layer, an inter-layer dielectric, a source/drain contact and a source/drain metal layer. The poly-silicon island is disposed on the substrate, wherein the poly-silicon island includes a source/drain and a channel disposed between the source/drain. The patterned gate dielectric layer is disposed above the channel of the poly-silicon island and the gate is disposed on the patterned gate dielectric layer. The silicide layer is formed above the source/drain of the poly-silicon island. The inter-layer dielectric covers the substrate. The source/drain contact is disposed in the inter-layer dielectric and the source/drain contact is electrically connected with the source/drain. The source/drain metal layer is disposed on the inter-layer dielectric, wherein the source/drain metal layer is electrically connected with the source/drain contact and electrically connected with the source/drain through the silicide layer.

According to an embodiment of the present invention, the material of the silicide layer is selected from one of PdSi—TiSi—NiSi—TiWSi—WSi—CoSi—TaSi—MoSi—PtSi—GeSi and the combination thereof.

According to an embodiment of the present invention, the foregoing thin film transistor further includes a buffer layer, disposed between the substrate and the poly-silicon island, wherein the material of the buffer layer can be silicon nitrides.

The present invention provides a pixel structure, suitable for the use in a display, the pixel structure includes a substrate, a poly-silicon island, a patterned gate dielectric layer, a gate, a silicide layer, an inter-layer dielectric, a source/drain contact, a source/drain metal layer, a patterned protecting layer and a pixel electrode. The poly-silicon island is disposed on the substrate, wherein the poly-silicon island includes a source/drain and a channel disposed between the source/drain. The patterned gate dielectric layer is disposed above the channel of the poly-silicon island and the gate is disposed on the patterned gate dielectric layer. The silicide layer is formed above the source/drain of the poly-silicon island. The inter-layer dielectric covers the substrate. The source/drain contact is disposed in the inter-layer dielectric and the source/drain contact is electrically connected with the source/drain. The source/drain metal layer is disposed on the inter-layer dielectric, wherein the source/drain metal layer is electrically connected with the source/drain contact and electrically connected with the source/drain through the silicide layer. The patterned protecting layer is disposed on the substrate, wherein the patterned protecting layer includes an opening to expose the source/drain metal layer. The pixel electrode is disposed on the patterned protecting layer, wherein the pixel electrode is filled in the opening to electrically connect with the source/drain metal layer.

According to an embodiment of the present invention, the material of the silicide layer is selected from one of PdSi—TiSi—NiSi—TiWSi—WSi—CoSi—TaSi—MoSi—PtSi—GeSi and the combination thereof.

According to an embodiment of the present invention, the foregoing thin film transistor further includes a buffer layer, disposed between the substrate and the poly-silicon island, wherein the material of the buffer layer can be silicon nitrides.

The invention adopts the silicide layer as an etching stopper. Therefore, the invention can manufacture source/drain contact holes with more precision tolerance only by using the dry etching. Besides, because the source/drain is covered by the silicide layer, the source/drain will not be damaged in the process of etching. Moreover, the silicide layer has good conductivity, which can reduce the contact resistance to improve the conductivity of the thin film transistor and further enhance the operating property of the thin film transistor.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1A to FIG. 1E are cross-sectional diagrams illustrating the steps of the method for manufacturing the conventional low temperature poly-silicon thin film transistor.

FIG. 2A to FIG. 2M are schematic diagrams illustrating the steps of the method for manufacturing a thin film transistor according to an embodiment of the present invention.

FIG. 3 is a cross-sectional diagram illustrating a thin film transistor according to an embodiment of the present invention.

FIG. 4 is a cross-sectional diagram illustrating a pixel structure to an embodiment of the present invention.

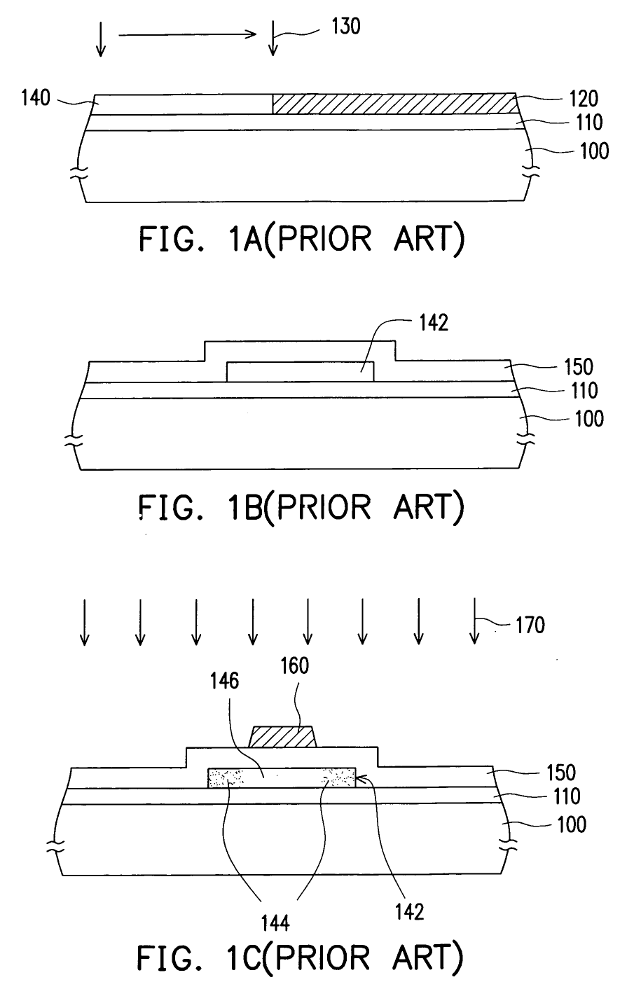

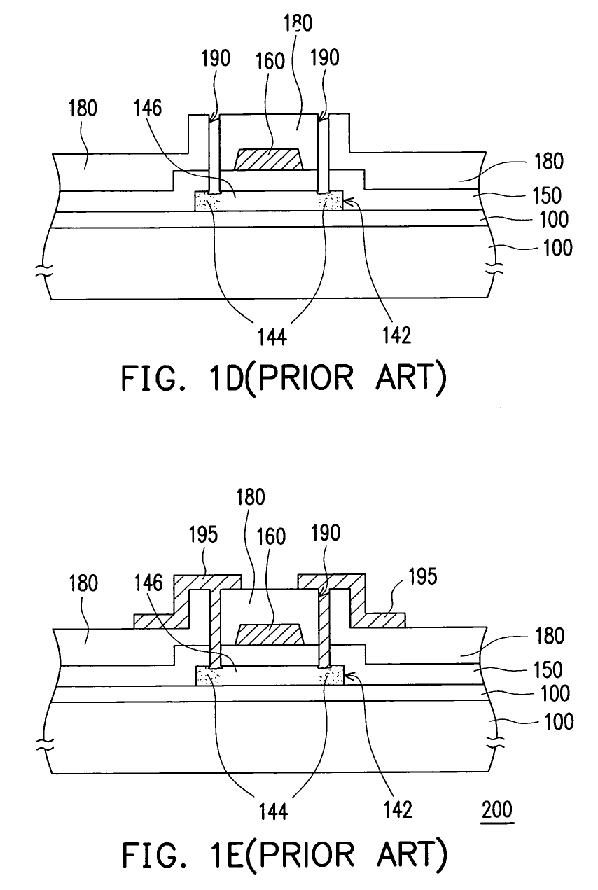

### DESCRIPTION OF THE EMBODIMENTS

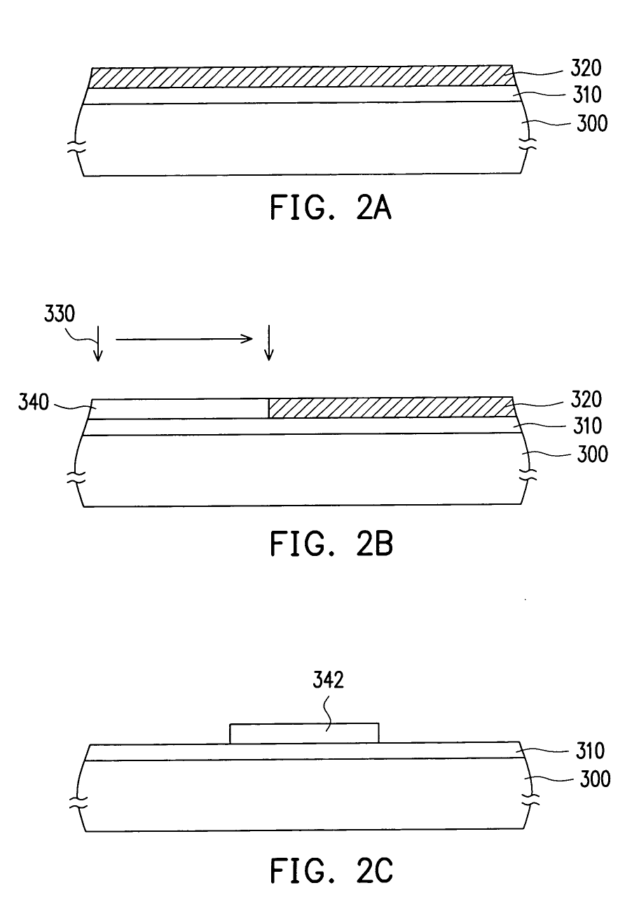

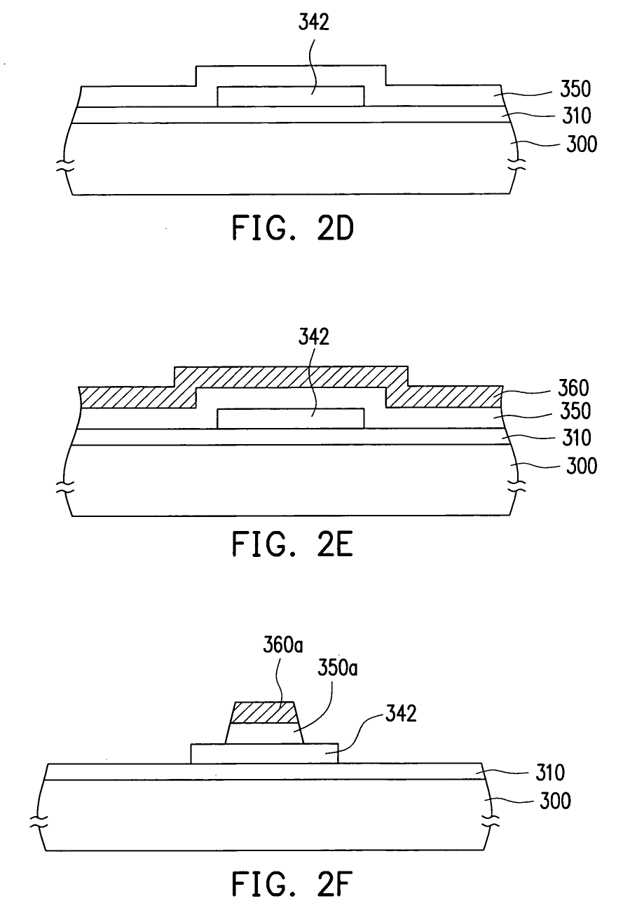

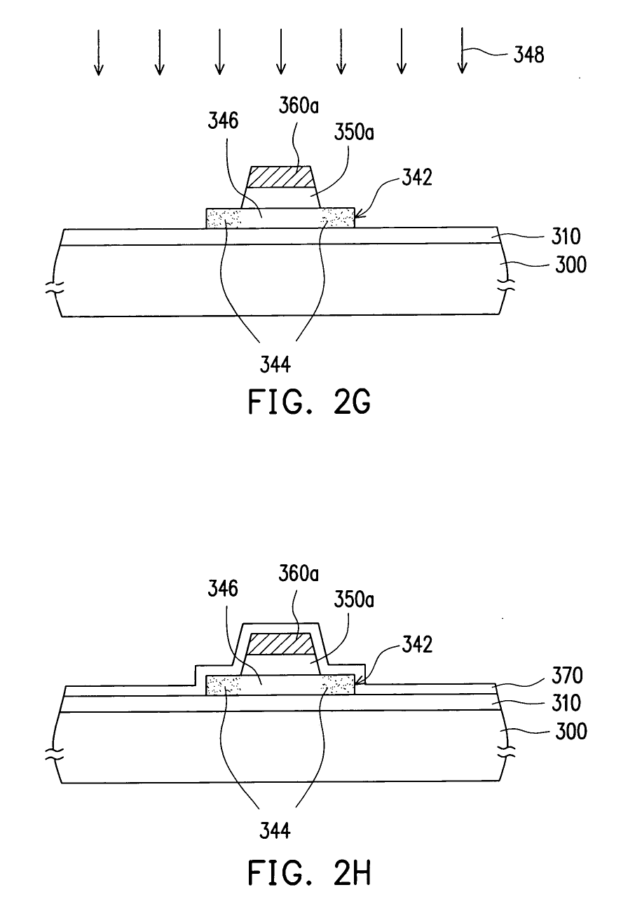

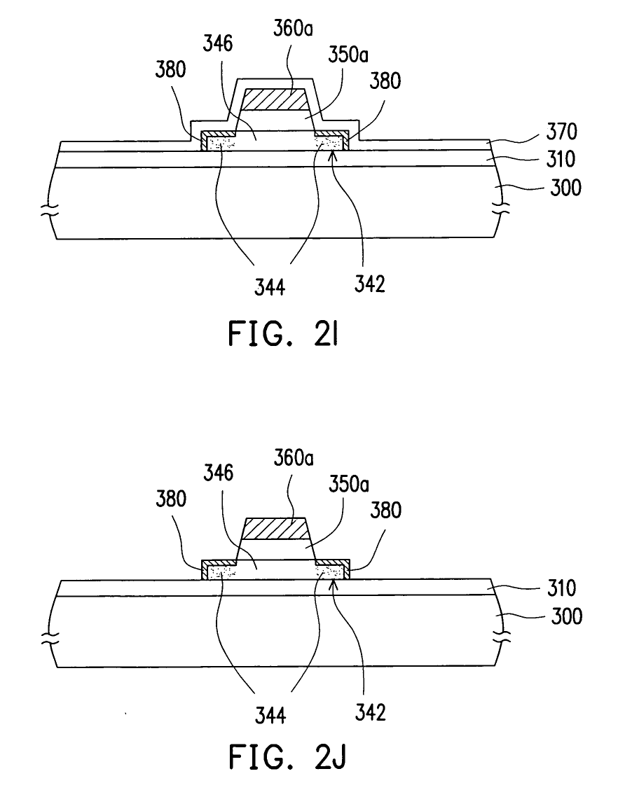

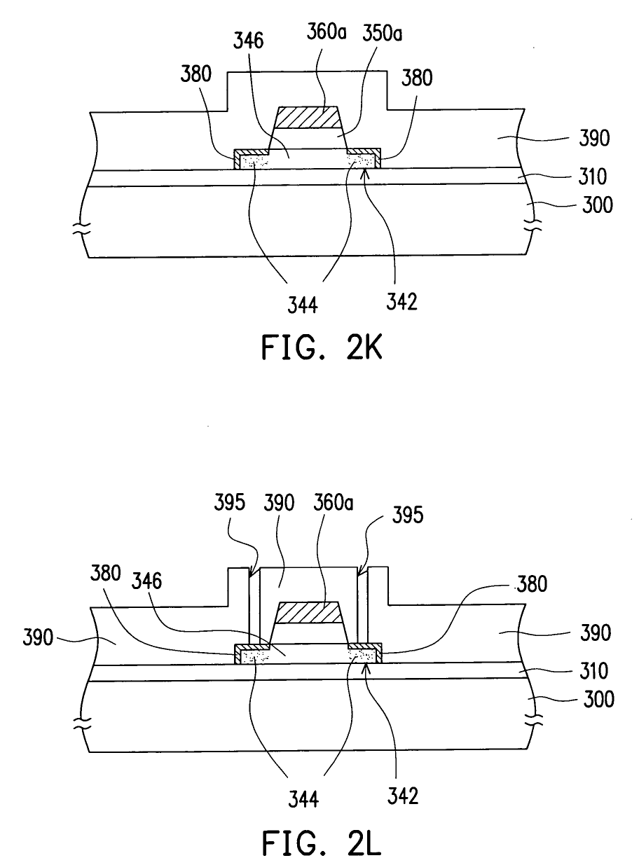

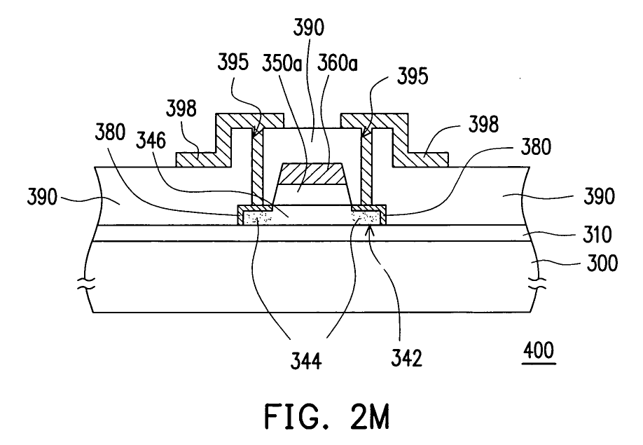

FIG. 2A to FIG. 2M are schematic diagrams illustrating the steps of the method for manufacturing a thin film transistor according to an embodiment of the present invention.

First, a poly-silicon island 342 is formed on the substrate 300 (as shown in FIG. 2C). In one embodiment, the method for forming the poly-silicon island 342 is to use the steps shown in FIG. 2A to FIG. 2C.

Please referring to FIG. 2A, an amorphous layer 320 is formed on the substrate 300, wherein the method for forming the amorphous layer 320 can be chemical vapor deposition (CVD). And the material of the substrate 300 can be glass. Next, as shown in FIG. 2B, the amorphous layer 320 is transformed into a poly-silicon layer 340. Then, as shown in FIG. 2C, the poly-silicon layer 340 is patterned to form a poly-silicon island 342 (only one is shown), wherein the method for transforming the amorphous layer 320 into the poly-silicon layer 340 can be excimer laser annealing (ELA) 330 or rapid thermal annealing (not shown). Besides, referring to FIG. 2A again, before forming the amorphous layer 320 on the substrate 300, a buffer layer 310 can be formed on the substrate 300. The material of the buffer layer 310 can be silicon nitrides and the method for forming the buffer layer 310 can be chemical vapor deposition. The buffer layer can enhance the adhesion between the amorphous layer 320 and the substrate 300.

Next, a patterned gate dielectric layer 350a and a gate 360a are formed on the poly-silicon island 342 (as shown in FIG. 2F). In one embodiment, the method for forming the patterned gate dielectric layer 350a and the gate 360a can use the steps shown in FIG. 2D to FIG. 2F. First, please referring to FIG. 2D, a gate dielectric layer 350 is formed on the substrate 300 to cover the poly-silicon island 342. The method for forming the gate dielectric layer 350 can be chemical vapor deposition. Next, referring to FIG. 2E, a gate material layer 360 is formed on the gate dielectric layer 350, wherein the method for forming the gate material layer 360 can be sputtering. Afterwards, referring to FIG. 2F, the gate material layer 360 and the gate dielectric layer 350 are patterned respectively to form the gate 360a and the patterned gate dielectric layer 350a. The patterned method uses the conventional photolithography/etching process so that unnecessary details are not given here.

Then, a source/drain 344 is formed in the poly-silicon island 342 beside the gate 360a, wherein a channel 346 is disposed between the source/drain 344 (as shown in FIG. 2G). In one embodiment, the method for forming the source/drain 344 can use an ion implantation process 348 with the gate 360a and the patterned gate dielectric layer 350a as the self-aligned mask to form the source/drain 344 in the poly-silicon island 342.

Furthermore, a metal layer 370 is formed on the substrate 300 to cover the gate 360a, the patterned gate dielectric layer 350a and the poly-silicon island 342 (as shown in FIG. 2H). In one embodiment, the method for forming the metal layer 370 can use sputtering or plasma deposition. Therefore, a homogeneous metal layer 370 is formed to cover the gate 360a, the patterned gate dielectric layer 350a and the poly-silicon island 342. The material of the metal layer 370 can be selected from one of palladium (Pd), titanium (Ti), nickel (Ni), WTi, tungsten (W), cobalt (Co), tantalum (Ta), molybdenum (Mo), platinum (Pt), germanium (Ge) and the combination thereof.

Moreover, the metal layer 370 and the poly-silicon island 342 above the source/drain 344 are reacted to form a silicide layer 380 (as shown in FIG. 21). In one embodiment, the method for forming the silicide layer 380 can be proceed with an annealing process, which can be thermal furnace annealing or rapid thermal annealing. In the process of the annealing, the poly-silicon and the metal layer 370 are reacted to form the silicide layer 380, and the crystal structure of the poly-silicon island 342 damaged by the foregoing process of ion implantation 348 (as shown in FIG. 2G) can be eliminated. Therefore, the stress in the poly-silicon island 342 can also be eliminated through the annealing process.

Then, the non-reacted metal layer 370 is removed (as shown in FIG. 2J). In one embodiment, the method for removing the non-reacted metal layer 370 can be a wet etching process. Because the etching characteristics of the silicide layer 380 and the metal layer 370 are different, the etching reagent that only etches the metal layer 370 can be chosen to remove the non-reacted metal layer 370. And the silicide layer 380 will not be etched at the same time.

Next, an inter-layer dielectric 390 is formed to cover the substrate 300 (as shown in FIG. 2K). In one embodiment, the method for forming the inter-layer dielectric 390 can be chemical vapor deposition and the material of the inter-layer dielectric 390 can be silicon nitrides.

Afterwards, the inter-layer dielectric 390 above the source/drain 344 is removed to form a source/drain contact hole 395, wherein the silicide layer 380 is used as an etching stopper (as shown in FIG. 2L). In one embodiment, the method for removing the inter-layer dielectric 390 above the source/drain 344 can be a photolithography process and a dry etching, wherein the silicide layer 380 is used as the etching stopper. The photolithography process and the dry etching are apparent to those skilled in the art and not further described herein. Accordingly, because the source/drain 344 is covered by the silicide layer 380, the source/drain 344 will not be damaged during etching the inter-layer dielectric 390.

In addition, after forming the source/drain contact hole 395, a source/drain metal layer 398 can be formed to fill in the source/drain contact hole 395 and electrically connect with the source/drain 344 (as shown in FIG. 2M). Hence, a thin film transistor 400 is formed. Accordingly, the silicide layer 380 has good conductivity and is disposed between the source/drain metal layer 398 and the source/drain 344. Therefore, the contact resistance in between can be reduced to improve the conductivity.

To sum up, by using the silicide layer as an etching stopper, the source/drain contact hole can be made with more precision tolerance only through dry etching. Besides, the source/drain is protected by the silicide layer so that it will not be damaged in the etching process. Furthermore, the silicide layer has good conductivity. Therefore, the contact resistance between the source/drain and the source/drain metal layer can be reduced to improve conductivity and further enhance the operating property of the thin film transistor.

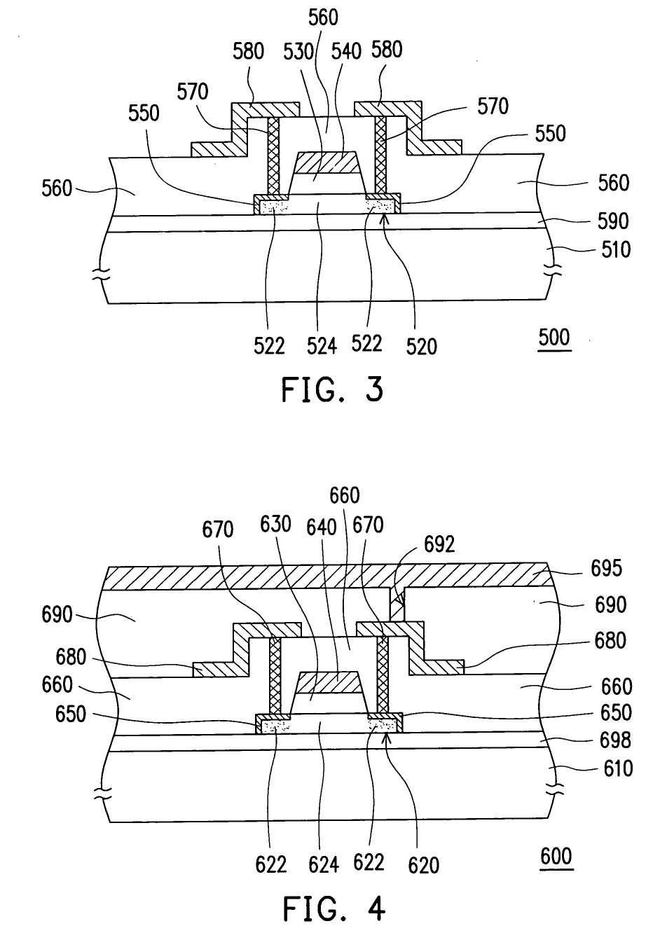

FIG. 3 is a cross-sectional diagram illustrating a thin film transistor according to an embodiment of the present invention, wherein the thin film transistor 500 is suitable for the use in a display (not shown) and can be liquid crystal display (LCD), organic electro-luminescence display (OLED), or plasma display, etc.

Referring to FIG. 3, the thin film transistor 500 includes a substrate 510, a poly-silicon island 520, a patterned gate dielectric layer 530, a gate 540, a silicide layer 550, an inter-layer dielectric 560, a source/drain contact 570 and a source/drain metal layer 580. Wherein, the poly-silicon island 520 is disposed on the substrate 510 and the poly-silicon island 520 includes a source/drain 522 and a channel 524 disposed between the source/drain 522. The patterned gate dielectric layer 530 is disposed above the channel 524 of the poly-silicon island 520 and the gate 540 is disposed on the patterned gatc dielectric layer 530. The silicide layer 550 is formed above the source/drain 522 of the poly-silicon island 520. The inter-layer dielectric 560 covers the substrate 510. The source/drain contact 570 is located in the inter-layer dielectric 560 and electrically connected with the source/drain 522. The source/drain metal layer 580 is disposed on the inter-layer dielectric 560, wherein the source/drain metal layer 580 is electrically connected with the source/drain contact 570 and electrically connected with the source/drain 522 through the silicide layer 550.

Accordingly, the thin film transistor 500 in the present invention includes a silicide layer 550, which is located between the source/drain 522 and the source/drain contact 570. In one embodiment, the material of the silicide layer 550 can be selected from one of PdSi—TiSi—NiSi—TiWSi—WSi—CoSi—TaSi—MoSi—PtSi—GeSi and the combination thereof. Because the silicide layer 550 has fine conductivity, the source/drain 522 and the source/drain contact 570 are well electrically-connected and further improve the operating property of the thin film transistor 500.

In addition, in one embodiment of the present invention, the thin film transistor 500 can further include a buffer layer 590, wherein the buffer layer 590 is disposed between the substrate 510 and the poly-silicon island 520 and the material of the buffer layer 590 can be silicon nitrides.

To sum up, the thin film transistor 500 with silicide layer 550 in the present invention is suitable for being used as the switches in various displays. Moreover, the silicide layer 550 can provide fine conductivity and further improve the operating property of the thin film transistor 500.

FIG. 4 is a cross-sectional diagram illustrating a pixel structure to an embodiment of the present invention. The pixel structure 600 is suitable for the use of a display (not shown), wherein the display can be liquid crystal display (LCD), organic electro-luminescence display (OLED), or plasma display, etc.

Referring to FIG. 4, the pixel structure 600 includes a substrate 610, a poly-silicon island 620, a patterned gate dielectric layer 630, a gate 640, a silicide layer 650, an inter-layer dielectric 660, a source/drain contact 670, a source/drain metal layer 680, a patterned protecting layer 690 and a pixel electrode 695. Wherein, the poly-silicon island 620 is disposed on the substrate 610 and the poly-silicon island 620 includes a source/drain 622 and a channel 624 disposed between the source/drain 622. The patterned gate dielectric layer 630 is disposed above the channel 624 of the poly-silicon island 620 and the gate 640 is disposed on the patterned gate dielectric layer 630. The silicide layer 650 is formed above the source/drain 622 of the poly-silicon island 620. The inter-layer dielectric 660 covers the substrate 610. The source/drain contact 670 is located in the inter-layer dielectric 660 and electrically connected with the source/drain 622. The source/drain metal layer 680 is disposed on the inter-layer dielectric 660, wherein the source/drain metal layer 680 is electrically connected with the source/drain contact 670 and electrically connected with the source/drain 622 through the silicide layer 650. The patterned protecting layer 690 is disposed on the substrate 610 and has an opening 692 to expose the source/drain metal layer 680. The pixel electrode 695 is disposed on the patterned protecting layer 690 and will fill in the opening 692 to electrically connect with the scurce/drain metal layer 680.

Accordingly, in one embodiment, the material of the silicide layer 650 can be chosen from one of PdSi—TiSi—NiSi—TiWSi—WSi—CoSi—TaSi—MoSi—PtSi—GeSi and the combination thereof. Those materials have good conductivity so that the source/drain 622 and the source/drain contact 670 can be well electrically-connected and the operating property of the pixel structure 600 can be improved.

Besides, the pixel structure 600 can further include a buffer layer 698, wherein the buffer layer 698 is disposed between the substrate 610 and the poly-silicon island 620 and the material of the buffer layer 698 can be silicon nitrides.

To sum up, the method for manufacturing thin film transistor, thin film transistor and pixel structure in the present invention have following advantages:

1. By using the silicide layer as an etching stopper, the source/drain contact hole can be fabricated with precision tolerance only through dry etching.

2. Because the source/drain is protected by the silicide layer, it will not be damaged in the etching process. Therefore, the operating property of the thin film transistor will not be affected.

3. Because the silicide layer has good conductivity so that the contact resistance between the source/drain and the source/drain metal layer can be reduced and the operating property of the thin film transistor can be improved.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A method for manufacturing thin film transistor comprising:
forming a poly-silicon island on a substrate;
forming a patterned gate dielectric layer and a gate on the poly-silicon island;
forming a source/drain in the poly-silicon island beside the gate, wherein a channel is disposed between the source/drain;
forming a metal layer on the substrate to cover the gate, the patterned gate dielectric layer and the poly-silicon island;
forming a silicide layer through the reaction of the metal layer and the poly-silicon island above the source/drain;
removing the non-reacted metal layer;
forming an inter-layer dielectric to cover the substrate; and
removing the inter-layer dielectric above the source/drain to form a source/drain contact hole, wherein the silicide layer is used as a etching stopper.

2. The method for manufacturing thin film transistor as recited in claim 1, wherein the method for forming the poly-silicon island on the substrate comprises:
forming an amorphous layer on the substrate;
transforming the amorphous layer into a poly-silicon layer; and
patterning the poly-silicon layer to form the poly-silicon island.

3. The method for manufacturing thin film transistor as recited in claim 2, wherein the method for transforming the amorphous layer into a poly-silicon layer comprises excimer laser annealing (ELA) or rapid thermal annealing (RTA).

4. The method for manufacturing thin film transistor as recited in claim 2, wherein before forming the amorphous layer on the substrate, the method further comprises forming a buffer layer on the substrate.

5. The method for manufacturing thin film transistor as recited in claim 4, wherein the material of the buffer layer comprises silicon nitrides.

6. The method for manufacturing thin film transistor as recited in claim 1, wherein the material of the metal layer is selected from one of palladium (Pd), titanium (Ti), nickel (Ni), TiW, tungsten (W), cobalt (Co), tantalum (Ta), molybdenum (Mo), platinum (Pt), germanium (Ge) and the combination thereof.

7. The method for manufacturing thin film transistor as recited in claim 1, wherein the method for forming the metal layer on the substrate comprises sputtering or plasma deposition.

8. The method for manufacturing thin film transistor as recited in claim 1, wherein the method for forming the silicide layer through the reaction of the metal layer and the poly-silicon island above the source/drain comprises an annealing process.

9. The method for manufacturing thin film transistor as recited in claim 1, wherein the method for removing the non-reacted metal layer comprises a wet etching process.

10. The method for manufacturing thin film transistor as recited in claim 1, wherein the method for removing the inter-layer dielectric above the source/drain comprises a photolithography process and a dry etching with the silicide layer being used as the etching stopper.

11. The method for manufacturing thin film transistor as recited in claim 1, wherein after forming the source/drain contact hole, the method further comprises forming a source/drain metal layer, which is filled with the source/drain contact hole and electrically connected to the source/drain.

12. A thin film transistor, suitable for the use in a display, the thin film transistor comprising:
a substrate;
a poly-silicon island, disposed on the substrate, wherein the poly-silicon island comprises a source/drain and a channel between the source/drain;
a patterned gate dielectric layer, disposed above the channel of the poly-silicon island;
a gate, disposed on the patterned gate dielectric layer;
a silicide layer, formed above the source/drain of the poly-silicon island;
an inter-layer dielectric, which covers the substrate;
a source/drain contact, disposed in the inter-layer dielectric and the source/drain contact is electrically connected with the source/drain; and
a source/drain metal layer, disposed on the inter-layer dielectric, wherein the source/drain metal layer is electrically connected with the source/drain contact and electrically connected with the source/drain through the silicide layer.

13. The thin film transistor as recited in claim 12, wherein the material of the silicide layer is selected from one of PdSi—TiSi—NiSi—TiWSi—WSi—CoSi—TaSi—MoSi—PtSi—GeSi and the combination thereof.

14. The thin film transistor as recited in claim 12, further comprising a buffer layer disposed betweep the substrate and the poly-silicon island.

15. The thin film transistor as recited in claim 14, wherein the material of the buffer layer comprises silicon nitrides.

16. A pixel structure, suitable for the use in a display, the pixel structure comprising:
a substrate;
a poly-silicon island, disposed on the substrate, wherein the poly-silicon island comprises a source/drain and a channel between the source/drain;
a patterned gate dielectric layer, disposed above the channel of the poly-silicon island;
a gate, disposed on the patterned gate dielectric layer;
a silicide layer, formed above the source/drain of the poly-silicon island;
an inter-layer dielectric, which covers the substrate;
a source/drain contact, disposed in the inter-layer dielectric and the source/drain contact is electrically connected with the source/drain;
a source/drain metal layer, disposed on the inter-layer dielectric, wherein the source/drain metal layer is electrically connected with the source/drain contact and electrically connected with the source/drain through the silicide layer;
a patterned protecting layer, disposed on the substrate, wherein the patterned protecting layer comprises an opening to expose the source/drain metal layer; and
a pixel electrode, disposed on the patterned protecting layer, wherein the pixel electrode is filled in the opening to electrically connected with the source/drain metal layer.

17. The pixel structure as recited in claim 16, wherein the material of the silicide layer is selected from one of PdSi—TiSi—NiSi—TiWSi—WSi—CoSi—TaSi—MoSi—PtSi—GeSi and the combination thereof.

18. The pixel structure as recited in claim 16, further comprising a buffer layer, disposed between the substrate and the poly-silicon island.

19. The pixel structure as recited in claim 18, wherein the material of the buffer layer comprises silicon nitrides.
